(19) United States
(12) Patent Application Publication
(10) Pub. No.: US 2009/0079045 A1
(43) Pub. Date: Mar. 26, 2009

(54) Package structure and manufacturing method thereof

(75) Inventor: Chih-Min Pao, Ciaotou Township (TW)

Correspondence Address: BACON & THOMAS, PLLC, 625 SLATERS LANE, FOURTH FLOOR, ALEXANDRIA, VA, 22314-1176, US

(73) Assignee: Advanced Semiconductor Engineering, Inc., Kaohsiung (TW)

(21) Appl. No.: 12/232,410

(22) Filed: Sep. 17, 2008

(30) Foreign Application Priority Data
Sep. 21, 2007 (TW) 96135510

(51) Int. Cl. H01L 23/495

(52) U.S. Cl. 257/666; 257/E23.031

(57) ABSTRACT

A quad-flat non-leaded (QFN) multichip package and a multichip package are provided. The QFN multichip package includes a lead frame, a first chip, a second chip and a molding compound. The lead frame has a plurality of first leads and second leads alternately arranged with each other. Each first lead includes a first connection portion and a first contact portion. Each second lead includes a second connection portion, a bending part and a second contact portion. The bending part is bent upward such that an interval is formed between the second contact portion and the first contact portion. The first chip is disposed between the first leads and the second leads. The second chip is disposed above the first chip. The molding compound encloses the first chip, the second chip, the first leads and the second leads, and further exposes the lower surfaces of the first and the second leads.

This application claims the benefit of Taiwan application Serial No. 96135510, filed Sep. 21, 2007, the subject matter of which is incorporated herein by reference.

### BACKGROUND OF THE INVENTION

1. Field of the Invention

The invention relates in general to a multichip package, and more particularly to a quad-flat non-leaded (QFN) multichip package.

2. Description of the Related Art

A generally known stackable semiconductor package is disclosed in U.S. Pat. No. 6,075,284. The inner leads of the lead frame are respectively extended upward and downward to form a pair of bumps such that the stackable package can be stacked face to face or back to back. However, it is very difficult to fabricate a lead frame in such particular shape by method of etching or punching. Moreover, that the leads of the lead frame are located at two lateral sides of the package is categorized as dual-in-line package (DIP) and cannot be used to pack die(s) with more electrodes as a quad flat package (QFP).

According to the shape of outer lead, the QFP structure can be divided into three types, namely, quad flat I-leaded (QFI) type, quad flat J-leaded (QFJ) type and quad flat non-leaded (QFN) type. With the design of hidden leads and tightly sticking to circuit board during bonding, the QFN package has smaller thickness to meets the demand of lightweight, thinness, simplicity and compactness for modern electronic elements, especially elements used in portable electronic devices such as mobile phone and notebook computer.

FIG. 1 shows a cross-sectional view of a generally known QFN package. The QFN package includes a lead frame 7, a chip 8 and a molding compound 9. The lead frame 7 has a plurality of leads 71 formed on the same plane, wherein each lead 71 has an upper surface 711 and a lower surface 712. The chip 8 is coupled to the upper surface 711 of the leads 71 of the lead frame 7 via a plurality of conductive elements 10 such as bumps. The molding compound 9 encloses the chip 8 and the leads 71 of the lead frame 7, and further exposes the lower surfaces 712 of the leads 71 of the lead frame 7 for electrically coupling to a circuit board. However, such QFN package can only be bonded to a circuit board by itself and cannot be stacked with one another, hence decreasing the space utilization of the circuit board and being unsuitable for a portable electronic device whose internal space is limited and requirement for function is high.

A generally known stackable QFN semiconductor package is disclosed in Japan Patent No. 10-74859. The stackable QFN package is obtained by disposing circuits with gold wires on the upper surface or lateral sides of a substrate for electrically connecting with a chip, and then forming a cavity in the middle of the substrate for receiving chip and forming conductive columns for electrically coupling upward and downward on the peripheral of the substrate via the DIP package disclosed in U.S. Pat. No. 6,020,629. However, the stackable QFN semiconductor package is disadvantaged by using a complicated substrate, not only being difficult to process but also incurring higher cost and increasing the thickness of the whole package structure.

### SUMMARY OF THE INVENTION

The invention is directed to a quad-flat non-leaded (QFN) multichip package capable of largely increasing the space utilization of circuit board and is applicable to a portable electronic device whose internal space is limited and requirement for function is high.

According to a first aspect of the present invention, a QFN multichip package is provided. The QFN multichip package is capable of stacking at least two chips by bending the leads of lead frame and has the advantages of low package thickness and simple structure.

According to a second aspect of the present invention, a QFN multichip package including a lead frame, a first flip-chip, a second flip-chip and a molding compound is provided. The lead frame has a plurality of first leads and second leads extending to different planes, wherein each first lead has a first upper surface and a first lower surface, and each second lead has a second upper surface and a second lower surface. The first flip-chip includes a plurality of first bumps coupled to the first upper surfaces of the first leads, wherein the first flip-chip is disposed between the first leads and the second leads. The second flip-chip includes a plurality of second bumps coupled to the second upper surfaces of the second leads, wherein the second flip-chip is disposed on the first flip-chip. The molding compound encloses the first flip-chip, the second flip-chip, the first leads and the second leads, and further exposes the first lower surfaces of the first leads and the second lower surfaces of the second leads.

According to a third aspect of the present invention, a QFN multichip package including a lead frame, a first flip-chip, a second flip-chip and a molding compound is provided. The lead frame has a plurality of first and second leads alternately arranged with each other. Each first lead includes a first connection portion and a first contact portion. Each second lead includes a second connection portion, a bending part and a second contact portion. The first and the second connection portions are electrically coupled to a circuit board. The first contact portions are formed on a first connection plane, and the second contact portions are formed on a second connection plane, wherein there is an interval between the first connection plane and the second connection plane. The first and the second connection portions of the first and the second leads are also formed on the first connection plane. The first flip-chip includes a plurality of first bumps coupled to the first contact portions of the first leads and is disposed between the first leads and the second leads. The second flip-chip includes a plurality of second bumps coupled to the second contact portions of the second leads and is disposed on the first flip-chip. The molding compound encloses the first flip-chip, the second flip-chip, the first leads and the second leads, and further exposes the lower surfaces of the first and the second connection portions of the first and the second leads.

According to a fourth aspect of the present invention, a multichip package including a first chip, a second chip, a lead frame, a plurality of first conductive element, a plurality of second conductive elements and a molding compound is provided. The first chip has a plurality of first pads. The second chip is disposed above the first chip and has a plurality of second pads. The lead frame has a plurality of first and second leads alternately arranged with each other. Each first lead includes a first connection portion and a first contact portion. Each second lead includes a second connection portion, a bending part and a second contact portion, wherein the first connection portions and the second connection portions are electrically coupled to an outer circuit. The first contact portions are formed on a first connection plane for electrically coupling to the first pads of the first chip, and the second contact portions are formed on a second connection plane for electrically coupling to the second pads of the second chip, wherein there is an interval between the first connection plane and the second connection plane. The first and the second connection portions of the first and the second leads are also formed on the first connection plane. The first conductive elements connect the first pads of the first chip with the first contact portions of the first leads. The second conductive elements connect the second pads of the second chip with the second contact portions of the second leads. The molding compound encloses the first chip, the second chip, the first leads, the second leads, the first conductive element and the second conductive elements, and further exposes the lower surfaces of the first and the second connection portions of the first and the second leads.

According to the QFN multichip package of the invention, a gap between the first chip and the second chip is filled with the molding compound.

According to the QFN multichip package of the invention, wherein the lateral surface of the molding compound is substantially flush with an end of the first connection portions of the first leads and an end of the second connection portions of the second leads.

According to the QFN multichip package of the invention, the size of the first chip is smaller or larger than that of the second chip.

The invention will become apparent from the following detailed description of the preferred but non-limiting embodiments. The following description is made with reference to the accompanying drawings.

### BRIEF DESCRIPTION OF THE DRAWINGS

FIG. 1 shows a cross-sectional view of a generally known QFN single-chip package;

FIG. 2 shows a cross-sectional view of a QFN multichip package according to a preferred embodiment of the invention;

FIG. 3 shows another cross-sectional view of the QFN multichip package of the invention; and

FIG. 4 shows an upper view of a stacked structure of a chip and a lead frame of the multichip package of the invention.

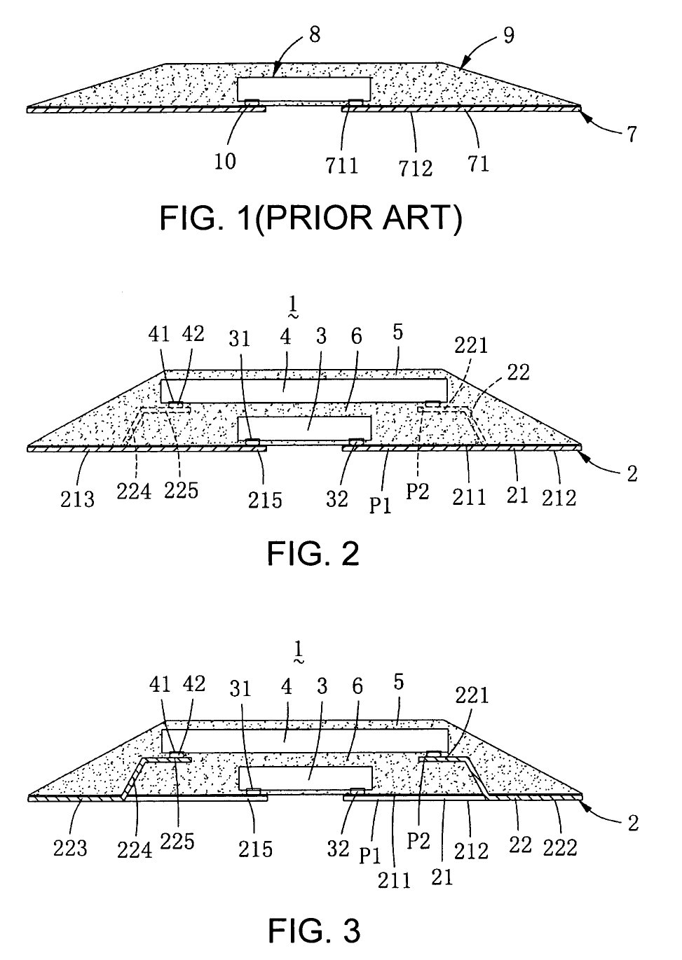

### DETAILED DESCRIPTION OF THE INVENTION

The objects, features and advantages of the invention are disclosed below in preferred embodiments of the invention with accompanying drawings.

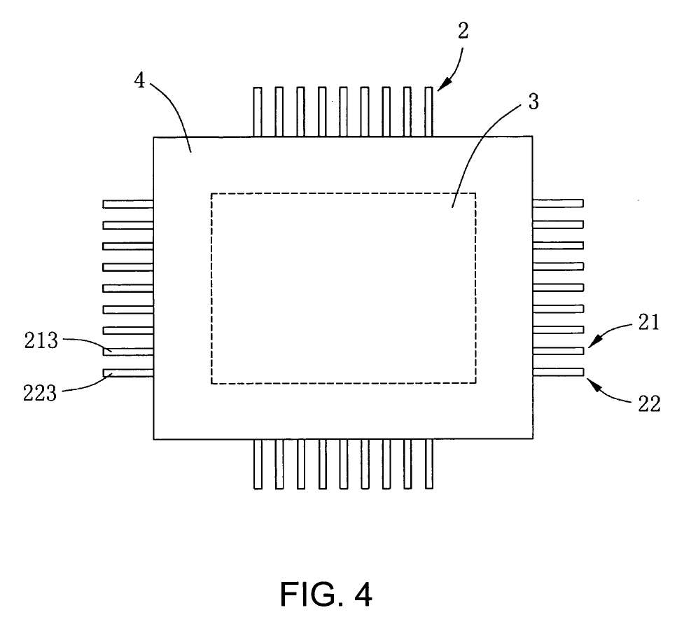

A quad-flat non-leaded (QFN) multichip package is disclosed in the invention. Referring to FIGS. 2, 3 and 4. FIG. 2 shows a cross-sectional view of a QFN multichip package according to a preferred embodiment of the invention. FIG. 3 shows another cross-sectional view of the QFN multichip package of the invention. FIG. 4 shows an upper view of a stacked structure of a chip and a lead frame of the multichip package of the invention. As indicated in FIG. 2 and FIG. 3, the QFN multichip package 1 of the invention mainly includes a lead frame 2, a first chip 3, a second chip 4 and a molding compound 5.

The lead frame 2 has a plurality of first leads 21 and second leads 22 extended to different planes, wherein each first lead 21 has a first upper surface 211 and a first lower surface 212, and each second lead 22 has a second upper surface 221 and a second lower surface 222. Each first lead 21 includes a first connection portion 213 and a first contact portion 215, wherein the upper surface of the first contact portions 215 is the first upper surface 211 of the first lead 21, and the lower surface of the first connection portion 213 is the first lower surface 212 of the first lead 21. Each second lead 22 includes a second connection portion 223, a bending part 224 and a second contact portion 225, wherein the bending part 224 is bent upward for connecting the second connection portion 223 and the second contact portions 225 such that the cross-section of the second lead 22 has a Z-shaped structure indicated in FIG. 3. The upper surface of the second contact portion 225 is the second upper surface 221 of the second lead 22, and the lower surfaces of the second connection portion 223 is the second lower surface 222 of the second lead 22.

The first connection portions 213 and the second connection portions 223 are for electrical coupling to an outer circuit such as a circuit board (not illustrated). The first contact portions 215 are electrically coupled to the first chip 3, and the second contact portions 225 are electrically coupled to the second chip 4. As indicated in FIG. 2, the first contact portions 215 are formed on a first connection plane P1, and the second contact portions 225 are formed on a second connection plane P2. As the bending part 224 disposed on the second lead 22 is bent upward so that an interval is formed between the first connection plane P1 and the second connection plane P2. The first and the second connection portions 213 and 223 of the first and the second leads 21 and 22 are disposed on the same plane, that is, the first connection plane P1 as indicated in FIG. 2. Furthermore, the first and the second connection portions 213 and 223 are alternately arranged with each other in parallel as indicated in FIG. 4.

In the present embodiment of the invention, the lead frame 2 is formed by the method of etching and is made from a group consisting of copper, copper-alloy or the like.

As indicated in FIG. 2, the bottom surface of the first chip 3 has a plurality of first pads 31. A plurality of first conductive elements 32 are combined with the first pads 31 so that the first chip 3 is coupled to the upper surface of the first contact portions 215 of the first leads 21 (that is, the first top surface 211 of the first leads 21) and the first chip 3 is disposed between the first leads 21 and the second leads 22.

As indicated in FIG. 2 and FIG. 3, the bottom surface of the second chip 4 also has a plurality of second pads 41. A plurality of second conductive elements 42 are combined with the second pads 41 so that the second chip 4 is coupled to the upper surface of the second contact portions 225 of the second leads 22 (that is, the second upper surface 221 of the second leads 22) and the second chip 4 is disposed above the first chip 3.

In the present embodiment of the invention, the first conductive elements 32 and the second conductive elements 42 both are conductive bumps such as solder bumps or Au bumps. That is, the first chip 3 and the second chip 4 are electrically connected with the lead frame 2 by flip-chip bonding. The first chip 3 and the second chip 4 of the invention can also be electrically connected with the lead frame 2 by wire bonding. The bonding wires are normally embodied as gold wires.

As indicated in FIG. 2 and FIG. 3, the molding compound 5 encloses the first chip 3, the second chip 4, the first leads 21 and the second leads 22, and further exposes the first lower surface 212 of the first leads 21 and the second lower surface 222 of the second leads 22. The lateral surface of the molding compound 5 is substantially flush with an end of the first connection portions 213 of the first leads 21 and an end of the second connection portions 223 of the second leads 22. A gap 6 is formed between the first chip 3 and the second chip 4 after the two chips are stacked together, wherein the gap 6 is filled with the molding compound 5. Preferably, the molding compound 5 is formed via molding.

In the embodiment of the invention as indicated in FIG. 2 to FIG. 4, two chips are stacked together. The size of the first chip 3 disposed underneath is smaller than the size of the second chip 4 disposed atop. However, the invention is not limited thereto. The spirit of the invention is also applicable to the stack of many chips, and the size of the first chip 3 disposed underneath can also be larger than the size of the second chip 4 disposed atop. Anyone who is skilled in the technology of the invention will understand that any variations and modifications made according to the spirit of the invention are still within the scope of protection of the invention.

As disclosed above, the invention obtains a QFN multichip package by the way of a lead frame 2 formed by a plurality of first leads 21 and second leads 22, wherein the second lead 22 has a bending part 224 bent upward between the connection portion 223 and the contact portion 225. The QFN multichip package of the invention is capable of stacking at least two chips, hence largely increasing the space utilization of the circuit board and being applicable to a portable electronic device whose internal space is limited and requirement for function is high. Compared with the prior art, the QFN multichip package of the invention has the advantages of low package thickness and simple structure.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A quad-flat non-leaded (QFN) multichip package, comprising:
a lead frame having a plurality of first and second leads extending to different planes, wherein each of the first leads has a first upper surface and a first lower surface, and each of the second leads has a second upper surface and a second lower surface;
a first flip-chip comprising a plurality of first bumps for coupling to the first upper surfaces of the first leads, the first flip-chip is disposed between the first leads and the second leads;
a second flip-chip comprising a plurality of second bumps for coupling to the second upper surfaces of the second leads, the second flip-chip is disposed above the first flip-chip; and
a molding compound enclosing the first flip-chip, the second flip-chip, the first leads and the second leads, wherein the first lower surfaces of the first leads and the second lower surfaces of the second leads are exposed outside of the molding compound.

2. The QFN multichip package according to claim 1, wherein each of the first leads comprises a first connection portion and a first contact portion, and each of second leads comprises a second connection portion, a bending part and a second contact portion; the first connection portions and the second connection portions are electrically coupled to an outer circuit, and the first contact portions are electrically coupled to the first flip-chip, and the second contact portions are electrically coupled to the second flip-chip.

3. The QFN multichip package according to claim 2, wherein there is an interval between the first contact portions of the first leads and the second contact portions of the second leads.

4. The QFN multichip package according to claim 2, wherein the first connection portions of the first leads and the second connection portions of the second leads are disposed on the same plane and alternately arranged with each other in parallel.

5. The QFN multichip package according to claim 1, wherein an interval between the first flip-chip and the second flip-chip is filled with the molding compound.

6. The QFN multichip package according to claim 5, wherein the size of the first flip-chip is smaller than that of the second flip-chip.

7. The QFN multichip package according to claim 5, wherein the size of the first flip-chip is larger than that of the second flip-chip.

8. A multichip package, comprising:
a first chip having a plurality of first pads;
a second chip disposed above the first chip having a plurality of second pads;
a lead frame having a plurality of first leads and a plurality of second leads, wherein the first leads and the second leads are alternately arranged with each other, and each of the first leads comprises a first connection portion and a first contact portion, each second lead comprises a second connection portion, a bending part and a second contact portion; the first connection portions and the second connection portions are electrically coupled to an outer circuit, and the first contact portions are formed on a first connection plane for electrically coupling to the first pads of the first chip; the second contact portions are formed on a second connection plane for electrically coupling to the second pads of the second chip, there is an interval between the first connection plane and the second connection plane, and the first and the second connection portions of the first and the second leads are also formed on the first connection plane;
a plurality of first conductive elements for connecting the first pads of the first chip with the first contact portions of the first leads;
a plurality of second conductive elements for connecting the second pads of the second chip with the second contact portions of the second leads; and
a molding compound enclosing the first chip, the second chip, the first leads, the second leads, the first conductive elements and the second conductive elements, wherein the lower surfaces of the first and the second connection portions of the first and the second leads are exposed outside of the molding compound.

9. The multichip package according to claim 8, wherein the second connection plane is disposed between the first chip and the second chip.

10. The multichip package according to claim 8, wherein the lateral surface of the molding compound is substantially flush with an end of the first connection portion of the first leads and an end of the second connection portion of the second leads.

11. The multichip package according to claim 8, wherein the multichip package is a stacked QFN chip package.

12. The multichip package according to claim 8, wherein a gap between the first chip and the second chip is filled with the molding compound.

13. The multichip package according to claim 8, wherein the size of the first chip of is smaller than that of the second chip.

14. The multichip package according to claim 8, wherein the size of the first chip is larger than that of the second chip.

15. A QFN multichip package, comprising:
a lead frame having a plurality of first and second leads alternately arranged with each other, wherein each of the first leads comprises a first connection portion and a first contact portion, and each of the second leads comprises a second connection portion, a bending part and a second contact portion; the first connection portions and the second connection portions are electrically coupled to a circuit board, and the first contact portions are formed on a first connection plane, and the second contact portions are formed on a second connection plane; there is an interval between the first connection plane and the second connection plane; the first and the second connection portions of the first and the second leads are also formed on the first connection plane;
a first flip-chip comprising a plurality of first bumps for coupling to the first contact portions of the first leads, the first flip-chip is disposed between the first leads and the second leads;
a second flip-chip comprising a plurality of second bumps for coupling to the second contact portions of the second leads, the second flip-chip is disposed above the first flip-chip; and
a molding compound enclosing the first flip-chip, the second flip-chip, the first leads and the second leads, wherein the lower surfaces of the first and the second connection portions of the first and the second leads are exposed outside of the molding compound.

16. The QFN multichip package according to claim 15, wherein the second connection plane is disposed between the first flip-chip and the second flip-chip.

17. The QFN multichip package according to claim 16, wherein a gap between the first flip-chip and the second flip-chip is filled with the molding compound.

18. The QFN multichip package according to claim 16, wherein the size of the first flip-chip is smaller than that of the second flip-chip.

19. The QFN multichip package according to claim 16, wherein the size of the first flip-chip is larger than that of the second flip-chip.
